(19) United States
(12) Patent Application Publication
(10) Pub. No.: US 2012/0003762 A1
(43) Pub. Date: Jan. 5, 2012

(54) Method to Protect Compound Semiconductor from Electrostatic Discharge Damage

(76) Inventors: Liann-Be Chang, Daxi Township (TW); Cheng-Chen Lin, Taichung City (TW)

(21) Appl. No.: 12/826,829

(22) Filed: Jun. 30, 2010

(51) Int. Cl. H01L 33/62

(52) U.S. Cl. 438/23; 257/E33.005; 257/E33.066; 257/E33.067

(57) ABSTRACT

A method to protect compound semiconductors from electrostatic discharge (ESD) damage, includes several processes as following: (a) forming a light emitting diode semiconductor over a substrate, in which the light emitting diode semiconductor has multi-layer structure and a first and a second electrodes; (b) forming a conductor-insulator-conductor (CIC) layers capacitance flip chip substrate including a first and a second conductive layers, and an insulator layer made of high-K material, in which the insulator layer is formed between the first and the second conductive layers, and there are a third and a fourth electrodes on the conductor-insulator-conductor layers substrate; and (c) electrically connecting the first electrode and the second electrode of the light emitting diode semiconductor to the third electrode and the fourth electrode of the conductor-insulator-conductor layers capacitance flip chip substrate, respectively, to effectively prevent from electrostatic discharge damage.

### BACKGROUND OF THE INVENTION

1. Field of Invention

The present invention relates to the technology of a method to protect semiconductors from electrostatic damage, specifically to a method to protect compound semiconductors from electrostatic discharge damage.

2. Description of the Related Art

The compound semiconductor element is often used for light-emitting device, and also needs to address the electrostatic problem, just like the other electronic components. Generally speaking, the anti-static manner for compound semiconductor element is often paralleling a Zener diode or a Schottky diode, or connecting to a filter circuit in series.

In recent years, III-V family compound semiconductors material with the potential used for optoelectronic and microwave devices attracts a lot of attention, especially the semiconductor material including III-V nitride, such as the semiconductor elements of GaN, AlGaN, and InGaN. However, since there is no natural formation of nitride homogeneous substrate, continuous epitaxy caused has resulted in an epitaxial layer with defects of high density, so as to lower the anti-static capability.

Referring to FIG. 5, which is a schematic view showing the circuit of the nitride element, in which the Zener diode parallels a flip chip semiconductor to prevent from electrostatic discharge damage. Wherein, a Zener diode (D2) is installed to parallel a flip chip semiconductor (D1), to prevent the flip chip semiconductor (D1) during operation from structural damage caused by electrostatic discharge, so as to achieve the effect of preventing from electrostatic discharge damage. When a normal forward bias applies to the two sides, V+ and V−, of the flip chip semiconductor (D1), the forward current is generated on the P-N junction of the flip chip semiconductor, and the flip chip semiconductor lights normally.

However, when abnormal voltage or electrostatic is generated, this too high voltage is discharged through the Zener diode operating in the crash area, in which the discharging path just passes through the Zener diode but not through the flip chip semiconductor, thus, the flip chip semiconductor does not be destroyed by abnormal voltage or high electrostatic, does not have irreversible damage, and operates normally.

FIG. 4 is a cross-section view of FIG. 5; and as shown in FIG. 4, semiconductor portion 61 includes a substrate 64, a first doped type doped GaN layer 66, a second doped type doped GaN layer 63 and an electrode, and protection portion 62 (a Zener diode) includes a first doped type doped silicon 65 (such as N-type), a second doped type doped silicon 67 (such as P++-type) and a metal layer. Wherein, the spherical region a solder ball, the second doped type doped silicon 67 electrically couples to the first doped type doped GaN layer 66, and the first doped type doped silicon 65 electrically couples to the second doped type doped GaN layer 63.

Under normal operations, a forward bias applies between V+ and V−, the current from the first doped type doped GaN layer 66 passes through the second doped type doped GaN layer 63, and the light produced emits through the transparent substrate 64. When abnormal voltage or electrostatic is generated, a discharged path is formed along the second doped type doped silicon 67 and the first doped type doped silicon 65, thus the charges do not pass through the protected semiconductor portion.

Although the above-mentioned structure achieves the effect for protecting the semiconductor portion from electrostatic discharge damage, the processes are difficult. Moreover, because the large forward current leakage problem exists in Zener diode, and the problems of external circuit cost and production, the above-mentioned structure is not ideal for components for preventing from electrostatic discharge.

### SUMMARY OF THE INVENTION

A method to protect compound semiconductors from electrostatic discharge (ESD) damage, includes several processes as following: (a) forming a light emitting diode semiconductor over a substrate, in which the light emitting diode semiconductor has multi-layer structure and a first and a second electrodes; (b) forming a conductor-insulator-conductor (CIC) layers capacitance flip chip substrate including a first and a second conductive layers, and an insulator layer made of high-K material, in which the insulator layer is formed between the first and the second conductive layers, and there are a third and a fourth electrodes on the conductor-insulator-conductor layers substrate; and (c) electrically connecting the first electrode and the second electrode of the light emitting diode semiconductor to the third electrode and the fourth electrode of the conductor-insulator-conductor layers capacitance flip chip substrate, respectively, to effectively prevent from electrostatic discharge damage.

Wherein, the high-K material layer is IrO² or HfO².

Wherein, the high-K material layer is Al²O³, Gd²O³, Pr²O³ or La²O³.

Wherein, the high-K material layer is rare-earth element oxide layer.

Wherein, the CIC layers capacitance flip chip substrate is semiconductor-high-k material-semiconductor layers substrate.

Wherein, the CIC layers capacitance flip chip substrate is metal-high-k material-semiconductor layers substrate.

Wherein, the CIC layers capacitance flip chip substrate is metal-high-k material-metal layers substrate.

Wherein, the electrical connection is for the first electrode and the second electrode of the light emitting diode semiconductor connecting to the third electrode and the fourth electrode of the CIC layers capacitance flip chip substrate through flip chip.

Wherein, the first electrode and the second electrode of the light emitting diode semiconductor connect to the third electrode and the fourth electrode of the CIC layers capacitance flip chip substrate through a solder ball, respectively.

Wherein, the another side of the second conductive layer relative to the high-k material layer is coated with a metal layer electrically connected to the third electrode or the fourth electrode.

Another method to protect compound semiconductors from electrostatic discharge damage of the present invention includes several processes as following:

forming a light emitting diode semiconductor over a substrate, in which the light emitting diode semiconductor has multi-layer structure and a first and a second electrodes;

forming a conductor-insulator-conductor (CIC) layers capacitance flip chip substrate including a first conductive layer, an insulator layer made of high-K material, and a metal layer, in which the insulator layer is formed between the first conductive layer and the metal layer, and there are a third and a fourth electrodes on the CIC layers capacitance flip chip substrate; and

electrically connecting the first electrode and the second electrode of the light emitting diode semiconductor to the third electrode and the fourth electrode of the CIC layers capacitance flip chip substrate, respectively; in which the another side of the metal layer relative to the high-k material layer is installed with an insulating substrate layer, and the third electrode and the fourth electrode electrically connect to the metal layer by way of adjacent structures connection.

### BRIEF DESCRIPTION OF THE DRAWINGS

FIG. 1 is a schematic view showing the connection of the embodiment of the present invention, in which the flip chip LED electrically connects to the structure of the CIC layers capacitance flip chip substrate;

FIG. 1A is a schematic view showing the structure of another embodiment of the present invention, in which the flip chip LED electrically connects to the structure of the CIC layers capacitance flip chip substrate;

FIG. 2 is a schematic view showing another connection of the embodiment of the present invention, in which the flip chip LED electrically connects to the structure of the CIC layers capacitance flip chip substrate;

FIG. 3 is a schematic view showing the circuit of the embodiment of the present invention;

FIG. 4 is a schematic view showing the structure, in which the conventional flip chip LED electrically connects to the silicon substrate Zener diode; and

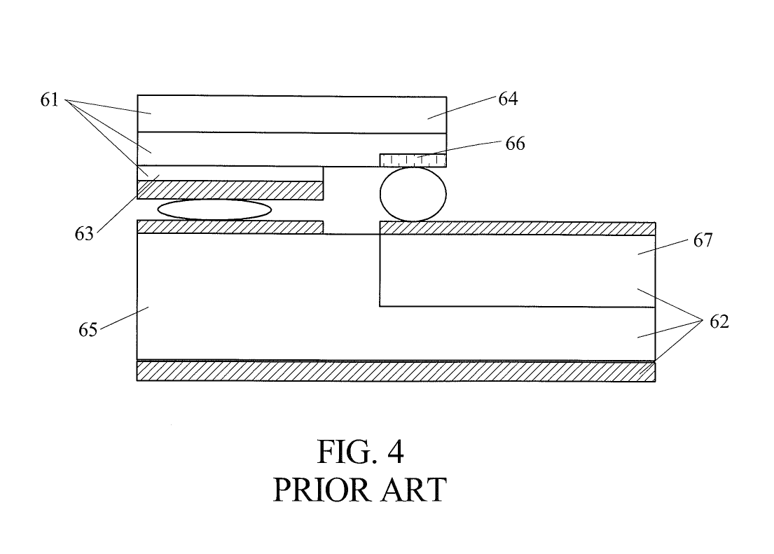

FIG. 5 is a schematic view showing the circuit of the conventional anti-static damage structure.

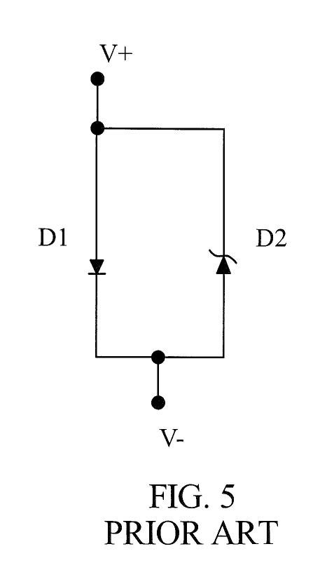

### DETAILED DESCRIPTION OF THE INVENTION

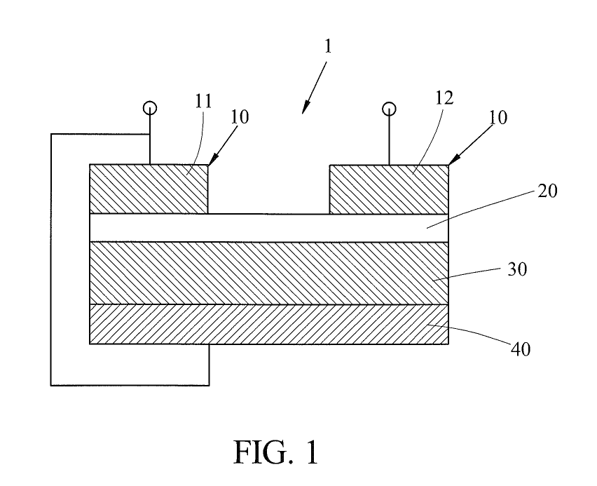

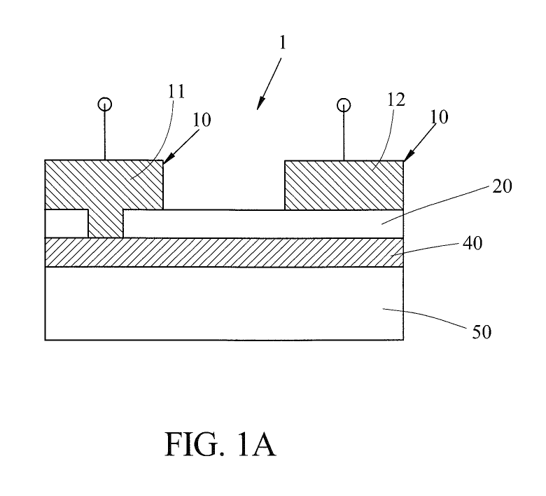

Referring to FIGS. 1 to 3, the present invention provides a method to protect compound semiconductors from electrostatic discharge damage, including several processes as following:

a. forming a light emitting diode semiconductor 70 over a substrate, in which the light emitting diode semiconductor 70 has multi-layer structure and a first electrode 71 and a second electrode 72;

b. forming a conductor-insulator-conductor (CIC) layers capacitance flip chip substrate 1 including a first conductive layer 10 and a second conductive layer 30, and an insulator layer 20 made of high-K material, in which the insulator layer 20 is formed between the first conductive layer 10 and the second conductive layer 30, and there are a third electrode 11 and a fourth electrode 12 on the conductor-insulator-conductor layers capacitance flip chip substrate 1; and
c. electrically connecting the first electrode 71 and the second electrode 72 of the light emitting diode semiconductor 70 to the third electrode 11 and the fourth electrode 12 of the conductor-insulator-conductor layers capacitance flip chip substrate 1, respectively.

Wherein, the high-K material layer is IrO² or HfO².

Wherein, the high-K material layer is Al²O³, Gd²O³, Pr²O³ or La²O³.

Wherein, the high-K material layer is rare-earth element oxide layer.

Wherein, the CIC layers capacitance flip chip substrate 1 is semiconductor-high-k material-semiconductor layers substrate.

Wherein, the CIC layers capacitance flip chip substrate 1 is metal-high-k material-semiconductor layers substrate.

Wherein, the CIC layers capacitance flip chip substrate 1 is metal-high-k material-metal layers substrate.

Wherein, the CIC layers capacitance flip chip substrate 1 includes a wire bond substrate and a surface mount type substrate.

Wherein, the CIC layers capacitance flip chip substrate 1 includes a single layer substrate or a multi-layer substrate.

Wherein, the surface mount type substrate is made through perforation or side plating.

Wherein, the electrical connection is for the first electrode 71 and the second electrode 72 of the light emitting diode semiconductor 70 connecting to the third electrode 11 and the fourth electrode 12 of the CIC layers capacitance flip chip substrate 1 through flip chip.

Wherein, the light emitted from the light emitting diode semiconductor 70 is directly emitted through the transparent substrate, and supported by a metal reflective layer to increase the efficiency.

Wherein, the light emitted from the light emitting diode semiconductor 70 is directly emitted through the transparent substrate, and supported by a Bragg reflective layer (DBR) to increase the efficiency.

Wherein, the light emitted from the light emitting diode semiconductor 70 is directly emitted through the transparent substrate, and supported by a metal reflective layer and a Bragg reflective layer (DBR) to increase the efficiency.

Wherein, a metal reflective layer of the light emitting diode semiconductor 70 uses silver (Ag) as the reflective layer, and is doped molybdenum (Mo), chrome (Cr) or palladium (Pd) for 1% to 12%.

Wherein, the first electrode 71 and the second electrode 72 of the light emitting diode semiconductor 70 connect to the third electrode 11 and the fourth electrode 12 of the CIC layers capacitance flip chip substrate through a solder ball, respectively.

Wherein, the another side of the second conductive layer 30 relative to the high-k material layer is coated with a metal layer 40 electrically connected to the third electrode 11 or the fourth electrode 12.

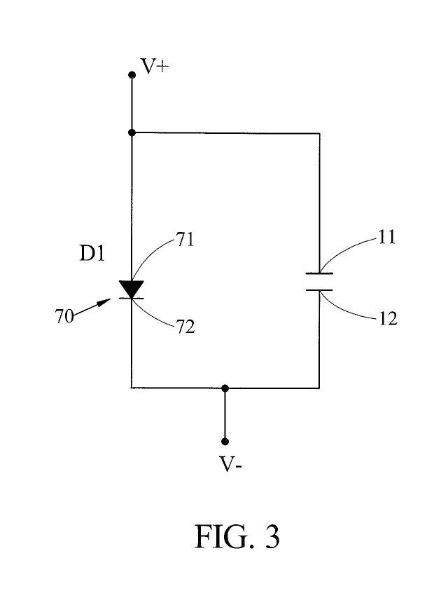

Referring to FIG. 3, which shows an equivalent circuit of the flip chip semiconductor structure shown in FIG. 1, and the semiconductor portion paralleling the protection portion. Under normal operations, a forward bias applies between V+ and V−, the current in the flip chip semiconductor (i.e. LED) (D1) from positive doped type doped layer passes through negative doped type doped layer, and the light produced emits through the transparent substrate. When abnormal voltage pulse or electrostatic pulse is generated, the charges discharge along the protection portion, i.e. between the first electrode 71 and the second electrode 72 on the CIC layers capacitance flip chip substrate 1, and does not pass through the semiconductor portion.

Currently, the high-K material mainly applies to the memory, such as DRAM, because the capacitor is the main component for charges storage, the need for a larger capacitance exists while shrinking in size, and the high-k material is available as an application. The capacitance formula is: C=(κ·∈₀·A)/t, in which C: capacitance, κ: relative permittivity, ∈₀: dielectric constant, A: capacitor area, t: capacitor thickness. Because capacitance is proportional to the value of κ, if relative permittivity κ of high-K material is higher, then capacitance is higher.

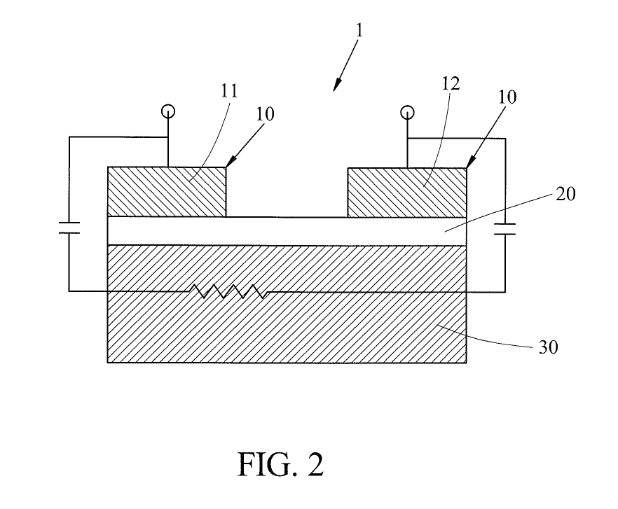

Referring to FIGS. 1 and 2, there are two kinds of connections in the embodiments of the present invention, and the capacitance in the connection shown in FIG. 1 is the double of that in FIG. 2. Thus, through the connection shown in FIG. 1, the compound semiconductors is more effectively protected from electrostatic discharge damage. Because the calculated capacitance of the connection shown in FIG. 2 is C=(C¹C²/(C¹+C²)), and the calculated capacitance of the connection shown in FIG. 1 is C=C¹ or C², the capacitance of the connection shown in FIG. 1 is the double of that in FIG. 2.

In addition, the present invention is also designed as another embodiment with the structure shown in FIG. 1A, and the present invention also provides a method to protect compound semiconductors from electrostatic discharge damage including several processes as following:

a. forming the light emitting diode semiconductor 70 over a substrate, in which the light emitting diode semiconductor 70 has multi-layer structure and the first electrode 71 and the second electrode 72;

b. forming a conductor-insulator-conductor (CIC) layers capacitance flip chip substrate including the first conductive layer 10, the metal layer 40, and the insulator layer 20 made of high-K material, in which the insulator layer 20 is formed between the first conductive layer 10 and the metal layer 40, and there are the third electrode 11 and the fourth electrode 12 on the conductor-insulator-conductor layers capacitance flip chip substrate; and

c. electrically connecting the first electrode 71 and the second electrode 72 of the light emitting diode semiconductor 70 to the third electrode 11 and the fourth electrode 12 of the conductor-insulator-conductor layers capacitance flip chip substrate, respectively; the another side of the metal layer 40 relative to the high-K material layer is installed with an insulating substrate layer 50, and the third electrode 11 and the fourth electrode 12 electrically connect to the metal layer 40 by way of adjacent structures connection; wherein, the first conductive layer 10 through the insulator layer 20 directly connects to the metal layer 40, the insulating substrate layer 50 is further adjacently installed at the bottom of the metal layer 40, and the P pole or N pole of the first conductive layer 10 directly connects to the metal layer 40, however, through experimental test, when the P pole connects to the metal layer 40, the antistatic protective effect and withstand voltage effect are better. Wherein, the metal layer 40 is a metal reflective layer, which is doped silver and molybdenum, to make upward light reflection, so as to increase light intensity.

In conclusion, by way of the insulator layer made of high-K material, such as IrO², HfO², Gd²O³or Al²O³, the present invention makes larger capacitance, to achieve better effect of protecting compound semiconductors from electrostatic discharge damage. Furthermore, the present invention adopts a different wiring way to double capacitance, so as to more effectively protect compound semiconductors from electrostatic discharge damage.

What is claimed is:

1. A method to protect compound semiconductors from electrostatic discharge damage, including several processes as following:
forming a light emitting diode semiconductor over a substrate, in which the light emitting diode semiconductor has multi-layer structure and a first and a second electrodes;
forming a conductor-insulator-conductor (CIC) layers capacitance flip chip substrate including a first and a second conductive layers, and an insulator layer made of high-K material, in which the insulator layer is formed between the first and the second conductive layers, and there are a third and a fourth electrodes on the conductor-insulator-conductor layers substrate; and
electrically connecting the first electrode and the second electrode of the light emitting diode semiconductor to the third electrode and the fourth electrode of the conductor-insulator-conductor layers capacitance flip chip substrate, respectively.

2. The method to protect compound semiconductors from electrostatic discharge damage as claimed in claim 1, in which the high-K material layer is IrO² or HfO².

3. The method to protect compound semiconductors from electrostatic discharge damage as claimed in claim 1, in which the high-K material layer is Al²O³, Gd²O³, Pr²O³ or La²O³.

4. The method to protect compound semiconductors from electrostatic discharge damage as claimed in claim 1, in which the high-K material layer is rare-earth element oxide layer.

5. The method to protect compound semiconductors from electrostatic discharge damage as claimed in claim 1, in which the CIC layers capacitance flip chip substrate is semiconductor-high-k material-semiconductor layers substrate.

6. The method to protect compound semiconductors from electrostatic discharge damage as claimed in claim 1, in which the CIC layers capacitance flip chip substrate is metal-high-k material-semiconductor layers substrate.

7. The method to protect compound semiconductors from electrostatic discharge damage as claimed in claim 1, in which the CIC layers capacitance flip chip substrate is metal-high-k material-metal layers substrate.

8. The method to protect compound semiconductors from electrostatic discharge damage as claimed in claim 1, in which the CIC layers capacitance flip chip substrate includes a wire bond substrate and a surface mount type substrate.

9. The method to protect compound semiconductors from electrostatic discharge damage as claimed in claim 1, in which the CIC layers capacitance flip chip substrate includes a single layer substrate or a multi-layer substrate.

10. The method to protect compound semiconductors from electrostatic discharge damage as claimed in claim 8, in which the surface mount type substrate is made through perforation or side plating.

11. The method to protect compound semiconductors from electrostatic discharge damage as claimed in claim 1, in which the electrical connection is for the first electrode and the second electrode of the light emitting diode semiconductor connecting to the third electrode and the fourth electrode of the CIC layers capacitance flip chip substrate through flip chip.

12. The method to protect compound semiconductors from electrostatic discharge damage as claimed in claim 1, in which the light emitted from the light emitting diode semiconductor is directly emitted through the transparent substrate, and supported by a metal reflective layer to increase the efficiency.

13. The method to protect compound semiconductors from electrostatic discharge damage as claimed in claim 1, in which the first electrode and the second electrode of the light emitting diode semiconductor connect to the third electrode and the fourth electrode of the CIC layers capacitance flip chip substrate through a solder ball, respectively.

14. The method to protect compound semiconductors from electrostatic discharge damage as claimed in claim 1, in which the another side of the second conductive layer relative to the high-k material layer is coated with a metal layer electrically connected to the third electrode or the fourth electrode.

15. A method to protect compound semiconductors from electrostatic discharge damage, including several processes as following:
forming a light emitting diode semiconductor over a substrate, in which the light emitting diode semiconductor has multi-layer structure and a first and a second electrodes;
forming a conductor-insulator-conductor (CIC) layers capacitance flip chip substrate including a first conductive layer, an insulator layer made of high-K material, and a metal layer, in which the insulator layer is formed between the first conductive layer and the metal layer, and there are a third and a fourth electrodes on the CIC layers capacitance flip chip substrate; and
electrically connecting the first electrode and the second electrode of the light emitting diode semiconductor to the third electrode and the fourth electrode of the CIC layers capacitance flip chip substrate, respectively; in which the another side of the metal layer relative to the high-k material layer is installed with an insulating substrate layer, and the third electrode and the fourth electrode electrically connect to the metal layer by way of adjacent structures connection.

16. The method to protect compound semiconductors from electrostatic discharge damage as claimed in claim 15, in which the high-K material layer is IrO² or HfO².

17. The method to protect compound semiconductors from electrostatic discharge damage as claimed in claim 15, in which the high-K material layer is Al²O³, Gd²O³, Pr²O³ or La²O³.

18. The method to protect compound semiconductors from electrostatic discharge damage as claimed in claim 15, in which the high-K material layer is rare-earth element oxide layer.

19. The method to protect compound semiconductors from electrostatic discharge damage as claimed in claim 15, in which the metal layer is metal reflective layer.
